(19) United States
(12) Patent Application Publication
(10) Pub. No.: US 2008/0265398 A1
(43) Pub. Date: Oct. 30, 2008

(54) SUBSTRATE WITH PIN, WIRING SUBSTRATE AND SEMICONDUCTOR DEVICE

(75) Inventors: Shunichiro MATSUMOTO, Nagano-shi (JP); Junichi NAKAMURA, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-Shi (JP)

(21) Appl. No.: 12/109,919

(22) Filed: Apr. 25, 2008

(30) Foreign Application Priority Data
Apr. 27, 2007 (JP) 2007-119011

(51) Int. Cl. H01L 23/498; H01R 12/00

(52) U.S. Cl. 257/697; 439/68; 257/E23.068

(57) ABSTRACT

A substrate with pins comprises pins, and a holding substrate in which through holes to which the pins are attached are formed. Head parts of the pins are arranged in the through holes. The pins are attached by pressing the head parts in the through holes.

This application claims priority to Japanese Patent Application No. 2007-119011, filed Apr. 27, 2007, in the Japanese Patent Office. The Japanese Patent Application No. 2007-119011 is incorporated by reference in its entirety.

### TECHNICAL FIELD

The present disclosure relates to a substrate with a pin used in a wiring substrate or a semiconductor device comprising a pin as an external connection terminal, and a semiconductor device and a wiring substrate using this substrate with the pin.

### RELATED ART

A PGA type semiconductor device has an advantage that the semiconductor device can be mounted by only inserting a pin into a socket and the need for a complicated step of mounting by solder reflow as described in a BGA type semiconductor device is eliminated. Further, the PGA type semiconductor device has an advantage that a product can be replaced by only reinserting the product, and is used in various electronic products.

In the PGA type semiconductor device, a product in which a substrate with pins formed by erecting pins in a substrate is assembled as an interposer has been proposed as a product constructed by bonding pins to a pad for pin bonding disposed on the mounting surface side of a wiring substrate (Patent References 1 to 3).

In the substrate with the pins used in these semiconductor device, the substrate with the pins is constructed by penetrating pin attachment holes in a substrate and inserting shaft parts of pins into the pin attachment holes. A semiconductor device is constructed by bonding head parts of the pins attached to the substrate with the pins to pads formed on a wiring substrate through a conductive material such as solder.

[Patent Reference 1] Japanese Patent Application Publication No. 7-169876

[Patent Reference 2] Japanese Patent Application Publication No 9-129778

[Patent Reference 3] Japanese Patent Application Publication No 2000-22019

In the product in which the semiconductor device is assembled using the substrate with the pins described above as the interposer, it is first necessary to form a through hole into which a shaft part of a pin is inserted in a substrate in the case of constructing the substrate with the pins. However, a diameter of the pin becomes extremely thin in a recent semiconductor device, so that there is a problem that work for forming the through hole into which the shaft part of the pin is inserted is complicated and inefficient. In some semiconductor device, through holes into which extremely many pins are inserted must be formed even for one substrate, so that it becomes a big problem in productivity of the semiconductor device.

Also, the substrate with the pins has a problem in reliability of bonding between a pin and a pad for pin connection formed in a wiring substrate.

### SUMMARY

Exemplary embodiments of the present invention provide a substrate with a pin in which the substrate with the pin used as an interposer constructing a semiconductor device can easily be manufactured and productivity of the substrate with the pin is improved and thus a manufacturing cost of a semiconductor package or a semiconductor device can be reduced, and a wiring substrate and a semiconductor device using this substrate with the pin.

The exemplary embodiments comprises the following configuration.

That is, a wiring substrate comprises a substrate, a pad formed on the side of one surface of the substrate, a pin electrically connected to the pad, and a holding substrate having a through hole for holding the pin, wherein a head part of the pin is arranged in the through hole.

Also, the fact that the head part is pressed in the through hole is effective in the respect that the pin is easily and surely supported in a holding substrate.

Also, it is effective in the respect that bonding to a pad of a wiring substrate can improve by protruding the top of the head part from a surface of the holding substrate.

Also, there is an advantage that attachment of a pin to a holding substrate improves by forming the head part in a taper shape in which a diameter of the top side expands.

Also, it is effective in the respect that a head part is surely fixed by an inner peripheral surface of a through hole or a holding substrate by forming a groove in a peripheral side surface of the head part.

Also, a wiring substrate can be constructed as a composite module by installing an electronic component in the holding substrate.

Also, a substrate with a pin, comprises a pin, and a holding substrate having a through hole to which the pin is attached, wherein a head part of the pin is arranged in the through hole. As a substrate with a pin, the substrate formed by pressing the head part in the through hole, the substrate formed by protruding the top of the head part from a surface of the holding substrate, the substrate formed by forming the head part in a taper shape in which a diameter of the top side expands, the substrate formed by forming a groove in a peripheral side surface of the head part, and the substrate formed by installing an electronic component in the holding substrate are used preferably.

Also, a semiconductor device comprises a semiconductor element, a substrate having a first electrode pad formed on a side of one surface of the substrate and a second electrode pad formed on a side of the other surface of the substrate, a pin electrically connected to the first electrode pad, and a holding substrate having a through hole corresponding to arrangement of the first electrode pad, wherein a head part of the pin is arranged in the through hole and the semiconductor element is electrically connected to the second electrode pad.

Also, pressing the head part in the through hole, protruding the top of the head part from a surface of the holding substrate, forming the head part in a taper shape in which a diameter of the top side expands, and forming a groove in a peripheral side surface of the head part are respectively effective, and there is an advantage of providing a semiconductor device as a composite module by installing an electronic component in the holding substrate.

According to the invention, a through hole in which a head part of a pin is arranged could be formed in a holding substrate constructing a substrate with a pin by being constructed so that the head part of the pin is arranged in the through hole of the substrate with the pin. Therefore, work for forming the through hole in the holding substrate by drilling etc. can become efficient effectively. Since a hole diameter of the through hole becomes large, an operation of laminating plural holding substrates and forming the through hole can also be performed and productivity of the substrate with the pin can be improved and thus, a manufacturing cost of a semiconductor device with the pin or a wiring substrate with the pin can be reduced.

Other features and advantages maybe apparent from the following detailed description, the accompanying drawings and the claims.

### BRIEF DESCRIPTION OF THE DRAWINGS

FIGS. 1A to 1C are sectional views showing a configuration of a substrate with pins according to the invention.

FIGS. 2A and 2B are sectional views showing other configurations of substrates with pins.

FIGS. 3A and 3B are sectional views showing a further configuration of a substrate with pins.

FIGS. 4A and 4B are sectional views showing a step of bonding a substrate with pins to a wiring substrate.

FIGS. 5A and 5B are sectional views showing a configuration of a semiconductor product formed by bonding a substrate with pins to a wiring substrate.

FIGS. 6A and 6B are sectional views showing other configurations of substrates with pins.

FIG. 7 is a sectional view showing other configuration of a substrate 26 with pins.

FIG. 8A is an example of bonding the substrate 26 with pins in FIG. 7 to a wiring substrate 30.

FIG. 8B is an example of a product in which a semiconductor element 35 is installed on the wiring substrate 30 and is electrically connected to the wiring substrate 30 by flip chip bonding in FIG. 8A.

FIGS. 9A to 9C are sectional views showing other configurations of substrates 27a, 27b, 27c with pins in which electronic components 60 are installed in the holding substrate 10 in FIG. 1c.

FIG. 10A is an example of bonding the substrate 27a with pins to a wiring substrate 30.

FIG. 10B is an example of a product in which a semiconductor element 35 is installed on the wiring substrate 30 and is electrically connected to the wiring substrate 30 by flip chip bonding in FIG. 10A.

### DETAILED DESCRIPTION

A preferred embodiment of the invention will hereinafter be described in detail with reference to the accompanying drawings.

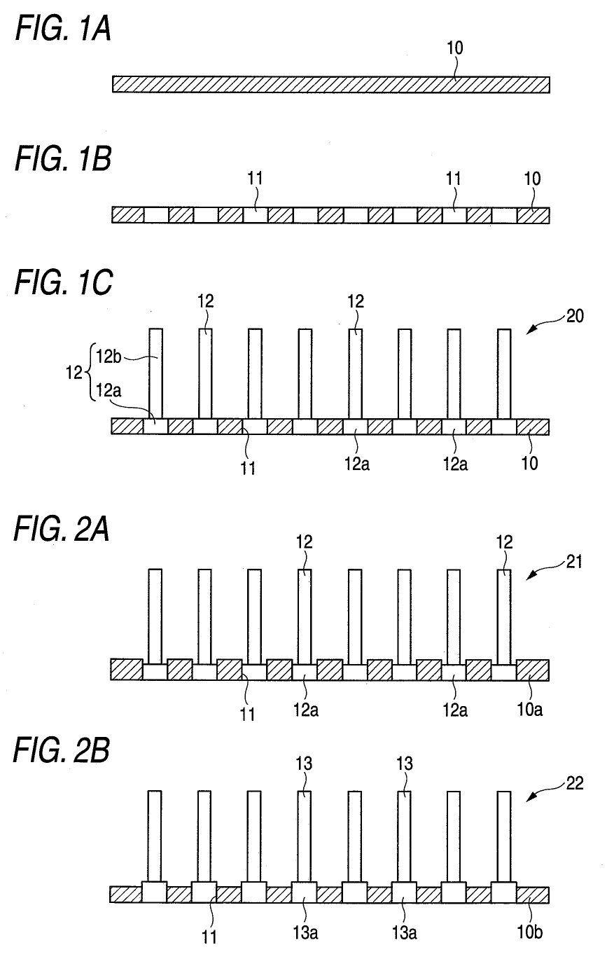

FIGS. 1A to 1C show a configuration of a substrate with pins according to the invention and its manufacturing step.

FIG. 1A shows a sectional view of a holding substrate 10 used in the substrate with the pins. The holding substrate 10 is a substrate made of a plate-shaped body such as a resin having electrical insulation properties. The holding substrate 10 supports a pin for connection and has a strength for supporting a wiring substrate bonded to the substrate with the pins so as not to warp the wiring substrate. For example, a resin material in which glass fibers are impregnated with an epoxy resin can be used.

FIG. 1B shows a state of forming through holes 11 in which head parts of pins are pressed and attached by boring holes in the holding substrate 10. The through holes 11 are formed in correspondence with plane arrangement of electrode pads in a wiring substrate to which the substrate with the pins is bonded. An arrangement distance between pins varies depending on a product and, for example, pitches 1.00 mm, 1.27 mm, 2.53 mm are used. Also, the number of pins attached to the holding substrate 10 varies depending on a size (plane area) of a semiconductor device and the arrangement distance between pins. A type with a large number of pins has about 1000 pins in one wiring substrate (semiconductor device).

The through hole 11 can be formed by, for example, drilling. A method for forming the through holes 11 in which head parts 12a of the pins 12 are pressed in the holding substrate 10 has an advantage capable of efficiently boring the holes in the holding substrate 10 as compared with a method for forming an insertion hole into which a pin body with a diameter thinner than that of a head part is inserted in a substrate as described in a related-art substrate with pins. For example, a diameter of a head part of a pin is about 0.5 to 0.75 mm and a diameter of a pin body of the pin in that case is about 0.3 mm. Thus, the through hole 11 in which the head part is pressed has a considerably larger diameter than that of a hole into which the pin body is inserted, so that hole boring is facilitated and the hole can also be formed by drilling with plural holding substrates stacked. The method for forming the through holes 11 in which the head parts of the pins are attached to the holding substrate 10 does not depend on a diameter of the pin body, so that the substrate with the pins can be constructed using a pin comprising a pin body with a diameter thinner than ever before.

FIG. 1C shows a state of forming a substrate 20 with pins by attaching the pins 12 to the holding substrate 10 in which the through holes 11 are formed.

The pin 12 comprises a pin body 12b inserted into and withdrawn from a socket, and the head part 12a with a diameter larger than that of the pin body 12b formed in the end of the pin body 12b. The pin 12 is attached so that the head part 12a is pressed in the through hole 11 formed in the holding substrate 10 and the pin body 12b stands up vertically with respect to a substrate surface of the holding substrate 10 and the pin body 12b extends from the holding substrate 10.

The pin 12 used in the substrate 20 with the pins of the embodiment is a pin in which an end face of the head part 12a is formed in a flat surface. The end face (top surface) of the head part 12a is flush with one surface (surface of the side opposite to a wiring substrate in the case of bonding the substrate with the pins to the wiring substrate) of the holding substrate 10 in a state of pressing the head part 12a in the through hole 11 of the holding substrate 10 and the endface of the head part 12a is exposed to an outer surface of the holding substrate 10 and also, one surface of the holding substrate 10 is formed in a flat surface as a whole. The pin body 12b of the pin 12 extends from the other surface of the holding substrate 10.

In the embodiment, a thickness of the head part 12a of the pin 12 is made equal to a thickness of the holding substrate 10 and the head part 12a is set so as to just sink in the through hole 11 of the holding substrate 10 in a state of pressing the head part 12a of the pin 12 in the through hole 11. In a pin in which a diameter of the head part is 0.5 to 0.75 mm, the thickness of the head part 12a is about 0.3 mm. In this example, a substrate with a thickness of 0.3 mm is used as the holding substrate 10.

When the thickness of the head part 12a of the pin 12 is made equal to the thickness of the holding substrate 10 as described in the embodiment, the thickness of the holding substrate 10 can be minimized without losing an attachment strength of the pin 12.

When it is necessary to use a holding substrate with some thickness in order to reinforce and support a wiring substrate, a holding substrate with a thickness thicker than that of the head part 12a of the pin 12 can also be used to form a substrate with pins. FIG. 2A shows a substrate 21 with pins formed by using a holding substrate 10a with a thickness thicker than that of the head part 12a of the pin 12.

A configuration in which the through holes 11 are formed in the holding substrate 10a and the head parts 12a of the pins 12 are pressed in the through holes 11 and the pins 12 are attached is similar to that of the substrate 20 with the pins shown in FIG. 1C described above. An end face of the head part 12a of the pin 12 is flush with one surface of the holding substrate 10a and is exposed to an outer surface of the substrate 21 with the pins.

On the other hand, when a head part of a pin is thicker than a thickness of a holding substrate constructing a substrate with pins, the head part protrudes from a substrate surface of the holding substrate. An example shown in FIG. 2B is an example of pressing head parts 13a in through holes 11 so that end faces (top surfaces) of the head parts 13a are flush with one surface of a holding substrate 10b and in this case, regions of the pin body sides of the head parts 13a of pins 13 protrude from the other surface of the holding substrate 10b.

In all of the substrates 20, 21, 22 with the pins described above, the pins 12, 13 are attached so that the end faces of the head parts 12a, 13a are flush with one surfaces of the holding substrates in surfaces opposite to wiring substrates of the substrates 20, 21, 22 with the pins. In order to make the end faces of the head parts 12a, 13a flush with the bonding surfaces of the substrates 20, 21, 22 with the pins thus, the pins 12, 13 could be pressed while supporting the holding substrates by a jig in which a receiving surface is formed in a flat surface in the case of pressing the pins 12, 13 in the holding substrates 10, 10a, 10b.

The side surfaces of the head parts 12a, 13a of the pins 12, 13 are formed in parallel with directions of shaft lines of the pins 12, 13 in cross-sectional shapes. The side surfaces of the through holes 11 formed in the holding substrates 10, 10a, 10b are formed in parallel with the directions of shaft lines of the pins 12, 13 in cross-sectional shapes and has inside diameters slightly smaller than outside diameters of the head parts 12a, 13a. The pins 12, 13 are constructed so as to be locked surely in the case of pressing the pins 12, 13.

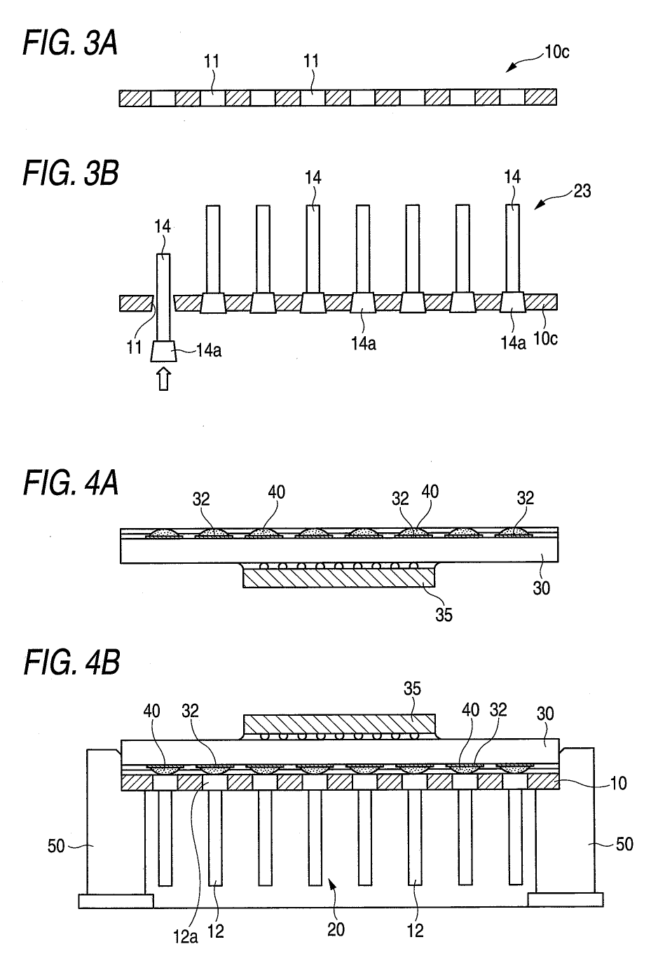

FIGS. 3A and 3B show that a substrate 23 with pins formed by attaching pins 14 comprising head parts 14a whose peripheral side surfaces are formed in taper shapes to a holding substrate 10c as another configuration example of the substrate with the pins. While side surfaces of the head parts 12a, 13a of both the pins 12, 13 used in the embodiment of the substrates with the pins described above are formed in parallel with directions of shaft lines of the pins 12, 13 in cross-sectional shapes, a side surface of the head part 14a of the pin 14 used in the embodiment is formed in a circular truncated conic shape in which a diameter of the end face (top) side expands and which is inclined to a direction of a shaft line of the pin 14 in a cross-sectional shape.

In the case of using the pin 14 in which the head part 14a is formed in the circular truncated conic shape, the pin 14 is attached to the holding substrate 10c so that the head part 14a is pressed in a through hole 11 formed in the holding substrate 10c from the diameter contraction side of the head part 14a as shown in FIG. 3B. Since a cross section of the head part 14a is formed in a taper surface, when the pin 14 is pressed in the through hole 11, the through hole 11 formed in the holding substrate 10c is pushed and the pin 14 is attached. A position of the pin 14 in the case of attaching the pin 14 to the holding substrate 10c can be adjusted by adjusting press-in force of the pin 14, an inside diameter of the through hole 11 and a taper angle of the peripheral side surface of the head part 14a formed in the pin 14. FIG. 3B shows a state of attaching the pin 14 in a state in which the end face (top surface) of the pin 14 slightly protrudes from a surface of the holding substrate 10c.

Thus, the substrate with the pins may be formed so that the end face (top surface) of the head part of the pin slightly protrudes from the surface of the holding substrate. Also, in some cases, it can be formed in a position in which the end face of the head part slightly enters into the holding substrate from the surface of the holding substrate.

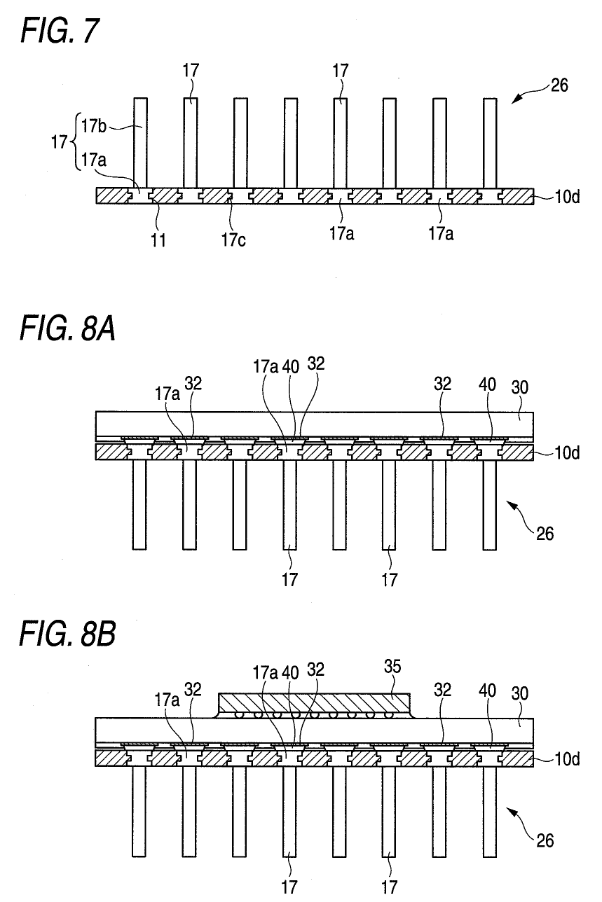

Also, the pin can surely be attached to the holding substrate by improving engagement between the holding substrate or the through hole 11 and the peripheral side surface of the head part by forming a groove in the peripheral side surface of the head part or forming the peripheral side surface of the head part in a roughened surface in order to ensure attachment of the pin to the holding substrate. FIG. 7 shows that a substrate 26 with pins formed by attaching pins 17 comprising head parts 17a having a groove 17c in the peripheral side surface to a holding substrate 10d as another configuration example of the substrate with the pins. When the pin 17 is pressed in a through hole 11 formed in the holding substrate 10d, a part of the holding substrate 10d is forced into the groove 17c of the head part 17a so that the pin 17 can surely be attached to the holding substrate 10d. In this embodiment, the head part 17a has one groove 17c which is formed in a direction along the periphery of the head part; however, it is not limited to this. For example, the headpart may have a plurality of grooves. Further, the groove may be formed in parallel with an axis of a pin body 17b.

In addition, a pin in which proper protective plating such as nickel plating processing or gold plating processing is performed on an outer surface of the pin can be used as the pin used in the substrate with the pins. A proper material such as copper or iron-nickel-cobalt alloy can be used as the material of the pin.

The substrate with the pins described above is provided as a semiconductor product by being bonded to a wiring substrate using a conductive material such as solder. FIGS. 4A and 4B show a method for forming a semiconductor device as a semiconductor product by bonding a substrate with pins to a wiring substrate.

FIG. 4A shows a state of supplying solder 40 to a pad 32 for pin connection of a wiring substrate 30 as a previous step of bonding a substrate with pins to a wiring substrate by solder. The solder 40 is supplied by, for example, a print method.

A configuration of the wiring substrate 30 is similar to a related-art configuration of a wiring substrate comprising pads for pin connection. The pads 32 for bonding pins are formed on the side of one surface to which the pins of the wiring substrate 30 are bonded, and a semiconductor element installation part is formed in the side of the other surface of the wiring substrate 30.

Electrode pads electrically connected to a semiconductor element are formed on the semiconductor element installation part disposed in the wiring substrate 30, and these electrode pads are electrically connected to the semiconductor element by flip chip bonding or wire bonding. FIG. 4A shows an example of installing a semiconductor element 35 by flip chip bonding.

In the embodiment, an example of bonding a substrate 20 with pins to the wiring substrate 30 after the semiconductor element 35 is installed on the wiring substrate 30 is shown, but the semiconductor element 35 can naturally be installed after the substrate 20 with pins is bonded to the wiring substrate 30.

FIG. 4B shows a state of bonding the substrate 20 with the pins to the wiring substrate 30 in are flow step. In there flow step, the substrate 20 with the pins and the wiring substrate 30 are supported by a support jig 50 and are passed through a reflow furnace and are bonded by solder. The substrate 20 with the pins and the wiring substrate 30 are supported with head parts 12a attached to the substrate 20 with the pins opposed to the pads 32 for connection of the wiring substrate 30. Since the head parts 12a of pins 12 attached to the substrate 20 with the pins are preset so that a plane arrangement position matches with the pads 32 for connection formed on the wiring substrate 30, the head parts 12a of the pins 12 are positioned in a one-to-one correspondence with the pads 32 of the wiring substrate 30 by aligning the wiring substrate 30 with the substrate 20 with the pins by the support jig 50.

As shown in FIG. 4B, the substrate 20 with the pins and the wiring substrate 30 are supported by the support jig 50 in a state of mutually abutting the bonding surfaces and are passed through the reflow furnace. Therefore, the solder 40 melts and the head parts 12a of the pins 12 attached to the substrate 20 with the pins are bonded to the pads 32 of the wiring substrate 30 by the solder.

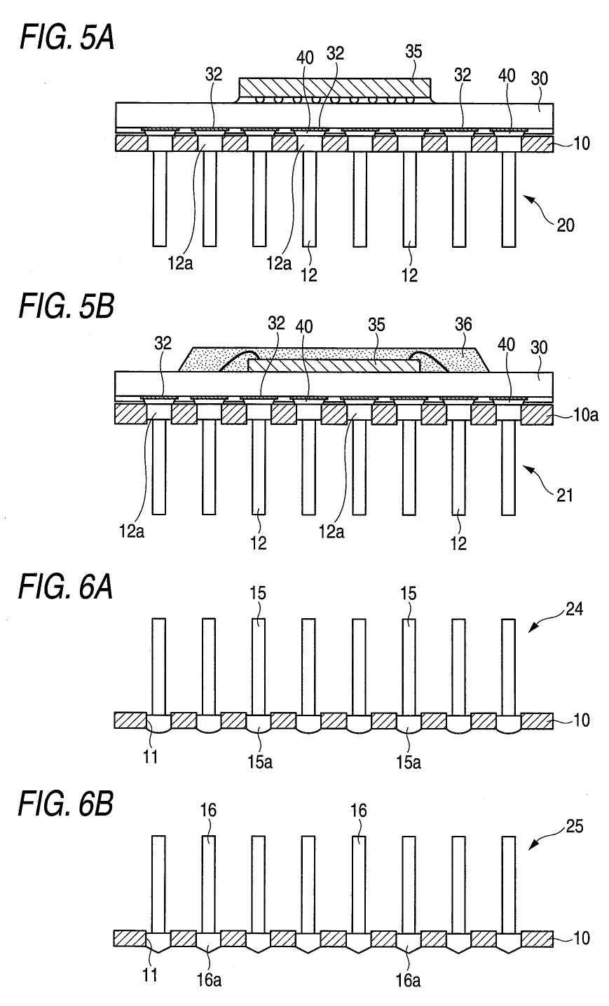

FIG. 5A is a state of bonding the substrate 20 with the pins to the wiring substrate 30 by solder. Each of the head parts 12a of the pins 12 attached to the substrate 20 with the pins are bonded to the pads 32 of the wiring substrate 30 by the solder 40. FIG. 5B is an example of a product in which the semiconductor element 35 installed on the wiring substrate 30 is electrically connected to the wiring substrate 30 by wire bonding and is sealed with a resin 36, and shows an example of using a holding substrate 10a with a thickness somewhat thicker than that of the substrate 20 with the pins of FIG. 5A as a substrate 21 with pins. FIGS. 8A and 8B show an example using the substrate 26 with pins in FIG. 7 in place of the substrate 20 with pins in FIG. 5A, and FIG. 8A is an example of bonding the substrate 26 with pins to a wiring substrate 30 and FIG. 8B is an example of a product in which a semiconductor element 35 is installed on the wiring substrate 30 and is electrically connected to the wiring substrate 30 by flip chip bonding in FIG. 8A.

According to the method for forming a semiconductor product by bonding the substrate 20 with the pins formed separately from the wiring substrate 30 to the wiring substrate 30 as described in the embodiment, there is an advantage capable of being applied as the wiring substrate 30 without changing a configuration of disposing the related-art pads 32 for pin connection, and an array of the pads 32 or sizes of the pads 32 can be designed on the premise that the head parts 12a of the pins 12 are bonded to the pads 32 by solder. Consequently, the pads 32 can be arranged at a density higher than ever before.

Also, in the substrate 20 with the pins, the pins 12 are supported in the holding substrate 10, so that it is unnecessary to guide and support each of the pins 12 by a jig as shown in a related-art support jig for supporting pins in the reflow step, and an operation of picking up a product from the support jig 50 is also simple. Further, a situation in which a substrate is deformed or a pin can not be taken in order to take the pin out of the support jig can be prevented. Also, a configuration of the support jig 50 can be simplified and the support jig 50 can be used in a versatile manner as long as it is a wiring substrate with the same outside dimension.

Also, the substrate 20 with the pins has a predetermined strength of reinforcing the wiring substrate 30, so that the substrate 20 with the pins is bonded to the wiring substrate 30 by solder and thereby, the wiring substrate 30 is reinforced and deformation in which the wiring substrate 30 warps can be suppressed. Even when the wiring substrate 30 is thin and does not have sufficient shape retention, a wiring substrate to which the substrate with the pins is bonded or a semiconductor device for preventing deformation of the wiring substrate 30 by bonding the substrate 20 with the pins can be provided. In addition, reinforcement as a semiconductor product can further be achieved by filling a gap of the part of bonding between the substrate 20 with the pins and the wiring substrate 30 with a resin for reinforcement after the substrate 20 with the pins is bonded to the wiring substrate 30 by solder.

As described above, the substrate 20 with the pins is finally bonded to the wiring substrate 30 by solder and the semiconductor device is constructed. The pins 12 attached to the substrate 20 with the pins are bonded to the wiring substrate 30 by solder and a bonding strength necessary to be inserted into and withdrawn from a socket can be obtained. Therefore, when the pins 12 are attached to the substrate 20 with the pins, the pins 12 could be supported to the extent that the pins 12 are not shifted or not taken out of the holding substrate 10 at the time of handling of bonding the substrate 20 with the pins to the wiring substrate 30. In the operation of pressing the pins 12 in the holding substrate 10 and attaching the pins 12 as described above, attachment capability of the pins 12 of this extent is ensured.

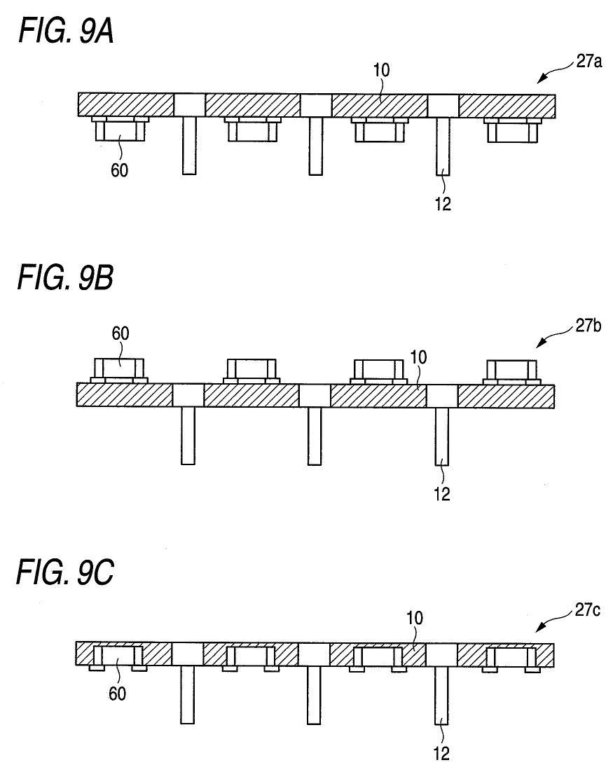

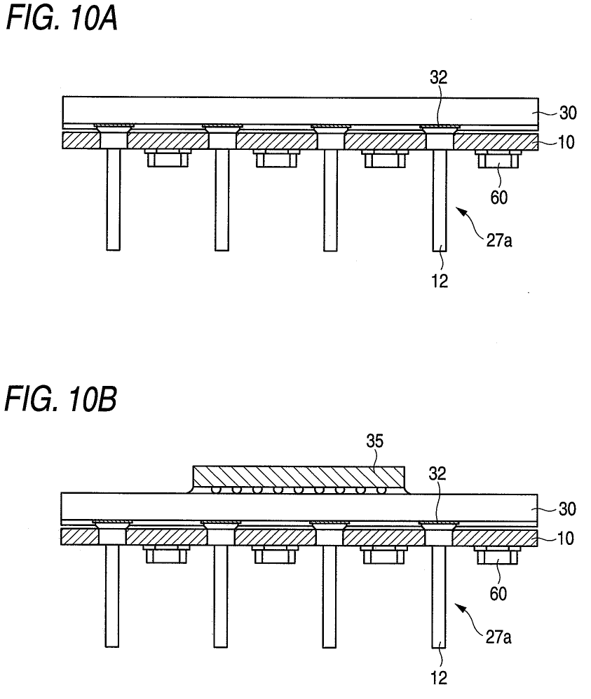

In addition, the substrate with the pins of the embodiment has been formed by attaching only the pins to the holding substrate, but a substrate with pins can be constructed by constructing a holding substrate modularized by installing an electronic component (circuit component) such as a resistor or a capacitor in the holding substrate in addition to the pins for connection and attaching the pins to the holding substrate, and a composite modularized semiconductor product can also be formed by bonding the substrate with the pins to a wiring substrate (FIGS. 9A to 9C and FIGS. 10A to 10B). FIGS. 9A to 9C show substrates 27a, 27b, 27c with pins in which electronic components 60 are installed on the holding substrate 10. FIG. 10A is an example of bonding the substrate 27a with pins to a wiring substrate 30 and FIG. 10B is an example of a product in which a semiconductor element 35 is installed on the wiring substrate 30 and is electrically connected to the wiring substrate 30 by flip chip bonding in FIG. 10A. In this case, the substrate with the pins can also be formed larger than the wiring substrate in order to obtain space for installing the circuit component. Also, it can be constructed so that a wiring pattern for being electrically connected to an electronic component is formed on a holding substrate and the electronic component is electrically connected to a head part through the wiring pattern.

Also, a method for disposing electrodes bonded to the pads 32 on a holding substrate and disposing a wiring pattern for electrically connecting the electrodes to head parts of the pins on the holding substrate and electrically bonding the pads 32 to the electrodes by a conductive material such as solder can be used as a method for electrically connecting the pins attached to the substrate with the pins to the pads 32 disposed on the wiring substrate 30.

FIGS. 6A and 6B show another example of pins attached to a holding substrate 10. In the embodiment described above, in all the pins 12, 13, 14, the end faces (top surfaces) of the head parts 12a, 13a, 14a have been formed in the flat surfaces, but as shown in FIG. 6A and 6B, pins in which an end face of a head part is formed in a curved surface such as a spherical shape or a circular conic surface shape or the tip side is formed in a sharp shape can also be used.

FIG. 6A is an example of a substrate 24 with pins formed by attaching pins 15 in which the end face sides (bonding surface sides) of head parts 15a are formed in spherical surfaces to the holding substrate 10, and FIG. 6B is an example of a substrate 25 with pins formed by attaching pins 16 in which the end face sides of head parts 16a are formed in circular conic surfaces to the holding substrate 10.

When the end faces of the head parts 15a, 16a of the pins 15 are formed in convex shapes as shown in these substrates 24, 25 with the pins, there are an advantage that when the substrates 24, 25 with the pins are aligned with the wiring substrate 30, the end faces of the head parts 15a, 16a abut on pads and the alignment becomes easy, and an advantage that void release action in the case of solder bonding and an area of bonding between solder and the end faces of the head parts of the pins increase and a strength of bonding between the pins 15, 16 and pads 32 improves.

While the invention has been described with respect to a limited number of embodiments, those skilled in the art, having benefit of this disclosure will appreciate that other embodiments can be devised which do not depart from the scope of the invention as disclosed herein. Accordingly, the scope of the invention should be limited only by the attached claims.

What is claimed is:

1. A wiring substrate comprising:
a substrate;
a pad formed on a side of one surface of said substrate;
a pin electrically connected to said pad; and
a holding substrate having a through hole for holding said pin,
wherein a head part of the pin is arranged in the through hole.

2. A wiring substrate as claimed in claim 1, wherein the head part is pressed in the through hole.

3. A wiring substrate as claimed in claim 1, wherein the top of the head part protrudes from a surface of the holding substrate.

4. A wiring substrate as claimed in claim 1, wherein the head part is formed in a taper shape in which a diameter of the top side expands.

5. A wiring substrate as claimed in claim 1, wherein a groove is formed in a peripheral side surface of the head part.

6. A wiring substrate as claimed in claim 1, wherein an electronic component is installed in the holding substrate.

7. A substrate with a pin, comprising:
a pin; and
a holding substrate having a through hole to which said pin is attached,
wherein a head part of the pin is arranged in the through hole.

8. A substrate with a pin as claimed in claim 7, wherein the head part is pressed in the through hole.

9. A substrate with a pin as claimed in claim 7, wherein the top of the head part protrudes from a surface of the holding substrate.

10. A substrate with a pin as claimed in claim 7, wherein the head part is formed in a taper shape in which a diameter of the top side expands.

11. A substrate with a pin as claimed in claim 7, wherein a groove is formed in a peripheral side surface of the head part.

12. A substrate with a pin as claimed in claim 7, wherein an electronic component is installed in the holding substrate.

13. A semiconductor device comprising:
a semiconductor element;
a substrate having a first electrode pad formed on a side of one surface of said substrate and a second electrode pad formed on a side of the other surface of the substrate;
a pin electrically connected to said first electrode pad; and
a holding substrate having a through hole corresponding to arrangement of the first electrode pad,
wherein a head part of the pin is arranged in the through hole and the semiconductor element is electrically connected to the second electrode pad.

14. A semiconductor device as claimed in claim 13, wherein the head part is pressed in the through hole.

15. A semiconductor device as claimed in claim 13, wherein the top of the head part protrudes from a surface of the holding substrate.

16. A semiconductor device as claimed in claim 13, wherein the head part is formed in a taper shape in which a diameter of the top side expands.

17. A semiconductor device as claimed in claim 13, wherein a groove is formed in a peripheral side surface of the head part.

18. A semiconductor device as claimed in claim 13, wherein an electronic component is installed in the holding substrate.
